(19) United States
(12) Patent Application Publication
(10) Pub. No.: US 2023/0215890 A1
(43) Pub. Date: Jul. 6, 2023

(54) High Dynamic Range, Backside-illuminated, Low Crosstalk Image Sensor with Walls Between Silicon Surface and First Layer Metal to Isolate Photodiodes

(71) Applicant: OmniVision Technologies, Inc., Santa Clara, CA (US)

(72) Inventors: Seong Yeol MUN, Santa Clara, CA (US); Duli MAO, Sunnyvale, CA (US); Bill PHAN, San Jose, CA (US)

(21) Appl. No.: 17/570,006

(22) Filed: Jan. 6, 2022

(51) Int. Cl. H01L 27/146; H04N 5/3745

(52) U.S. Cl. CPC H01L 27/1463; H04N 5/3745; H01L 27/14645; H01L 27/14621; H01L 27/14627; H01L 27/14636; H01L 27/1464; H01L 27/14685; H01L 27/14689

(57) ABSTRACT

A backside-illuminated image sensor includes arrayed photodiodes separated by isolation structures, and interlayer dielectric between first layer of metal interconnect and substrate. The image sensor has barrier metal walls in the interlayer dielectric between isolation structures and first layer interconnect, the barrier metal walls aligned with the isolation structures and disposed between the isolation structures and first layer interconnect. The barrier metal wall deflects light passing through photodiodes of the sensor that would otherwise be reflected by interconnect into different photodiodes. The sensor is formed by providing a partially fabricated semiconductor substrate with photodiodes and source-drain regions formed; forming gate electrodes on a frontside surface of the semiconductor substrate, depositing an etch-stop layer over the gate electrodes; depositing interlayer dielectric on the etch-stop layer; forming trenches extending to the etch-stop layer through the interlayer dielectric, the trenches being between photodiodes; and filling trenches with metal to form barrier metal walls.

### BACKGROUND

Some backside-illuminated image sensors provide each pixel with two paired photodiodes, one large and one small, to provide high dynamic range imaging. In operation, the small photodiodes are used to resolve pixel data in bright portions of an image, and the large photodiodes are used to resolve pixel data in dim or dark portions of the image.

The large photodiodes of such image sensors are particularly useful for resolving weakly-illuminated pixels of an image, while the smaller photodiodes are particularly useful for resolving brightly-illuminated pixels of the image, providing greater dynamic range imaging than image sensors with same-size photodiodes throughout.

### SUMMARY

In an embodiment, a backside-illuminated image sensor includes an array of photodiodes electrically isolated by isolation trenches, an interlayer dielectric disposed between a first layer of metal interconnect and the semiconductor substrate. The image sensor includes a plurality of barrier metal walls disposed in the interlayer dielectric between the isolation trenches and the first layer of metal interconnect, the barrier metal walls being aligned with the isolation trenches. Each barrier metal wall serves to deflect light that has passed through a photodiode of the array of photodiodes and would otherwise be reflected by the first layer of metal interconnect into a different photodiode (e.g., adjacent photodiode) of the array of photodiodes.

In another embodiment, a method of fabricating a backside-illuminated image sensor includes forming a plurality of photodiodes and source-drain regions in a semiconductor substrate; forming at least one gate electrode on a front side surface of the semiconductor substrate depositing an etch-stop layer over the at least one gate electrode on the front side surface of the semiconductor substrate; depositing an interlayer dielectric on the etch-stop layer; forming one or more trenches through the interlayer dielectric and extending to but not through the etch-stop layer, wherein each of the one or more trenches is formed between a first photodiode and a second photodiode of the plurality of photodiodes; and filling the one or more trenches with metal to form one or more barrier metal walls.

### BRIEF DESCRIPTION OF THE FIGURES

FIG. 1 is a cross section of a small portion of a backside-illuminated image sensor, illustrating paths for light that may produce optical crosstalk between photodiodes of a photodiode array of the image sensor.

FIG. 2 is a cross section of an embodiment illustrating where barrier walls are provided between photodiodes in a backside-illuminated image sensor to prevent optical crosstalk between photodiodes.

FIG. 3 is detailed cross section of an embodiment illustrating a metal wall between photodiodes of a backside-illuminated image sensor.

FIG. 4 is a flowchart illustrating an exemplary method of fabricating a pixel array with barrier wall structure described in FIG. 2 and FIG. 3.

FIGS. 5A-5F illustrate cross-section views of a pixel array with barrier walls during various stages of fabrication in accordance with the teachings of the present invention.

FIG. 6 is a cross section of another embodiment illustrating where barrier walls provided between photodiodes are grounded in accordance with the teachings of the present invention.

FIGS. 7A-7B are exemplary top plan views of a pixel layout incorporating the barrier walls between photodiodes in accordance with the teachings of the present invention.

FIG. 8 is another exemplary top plan view of a pixel layout incorporating the barrier walls between large and small photodiodes in a pixel array having four-share pixels.

### DETAILED DESCRIPTION OF THE EMBODIMENTS

In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the terms “below” and “under” may encompass both an orientation of above and below. The device may be otherwise oriented (rotated ninety degrees or at other orientations) and the spatially relative descriptors used herein interpreted accordingly. In addition, it will also be understood that when a layer is referred to as being “between” two layers, it may be the only layer between the two layers, or one or more intervening layers may also be present.

The term isolation trench structure may refer to an isolation structure in between photodiodes in a pixel array for providing electrical and/or optical isolation between adjacent photodiodes. The isolation trench structure may be an oxide-filled isolation trench structure, a metal-filled isolation structure or a combination thereof. The isolation trench structure may be a front-side deep trench isolation structure extending from a front side of a substrate toward a backside of the substrate or a backside deep trench isolation structure extending from the backside of the substrate toward the front side of the substrate.

The term semiconductor substrate may refer to substrates formed of one or more semiconductors such as silicon, silicon-germanium, germanium, gallium arsenide, indium gallium arsenide, and other semiconductor materials known to those of skill in the art. The term semiconductor substrate may also refer to a substrate, formed of one or more semiconductors, subjected to previous process steps that form regions and/or junctions in the substrate. A semiconductor substrate may also include various features, such as doped and undoped semiconductors, epitaxial layers of silicon, and other semiconductor structures formed upon the substrate. It should be noted that element names and symbols may be used interchangeably through this document (e.g., Si vs. silicon); both have identical meanings.

Two-photodiode-per-pixel, backside-illuminated, image sensors may have their dynamic range increased by adding a neutral-density, light-absorbing, filter to reduce light sensitivity of a small photodiode in each pair of two photodiodes. When imaging brightly-illuminated pixels of an image with this light-absorbing filter present, we have observed that some light leaks into the small photodiodes that has entered the image-sensor array through adjacent large photodiodes, causing crosstalk that limits dynamic range of the image sensor by inducing photocurrent in the small photodiodes, and in some cases even saturates small photodiodes during integration of image sensor.

It is therefore desirable to reduce light leakage from large, dim-light sensing, photodiodes into the adjacent small bright-light sensing small photodiodes.

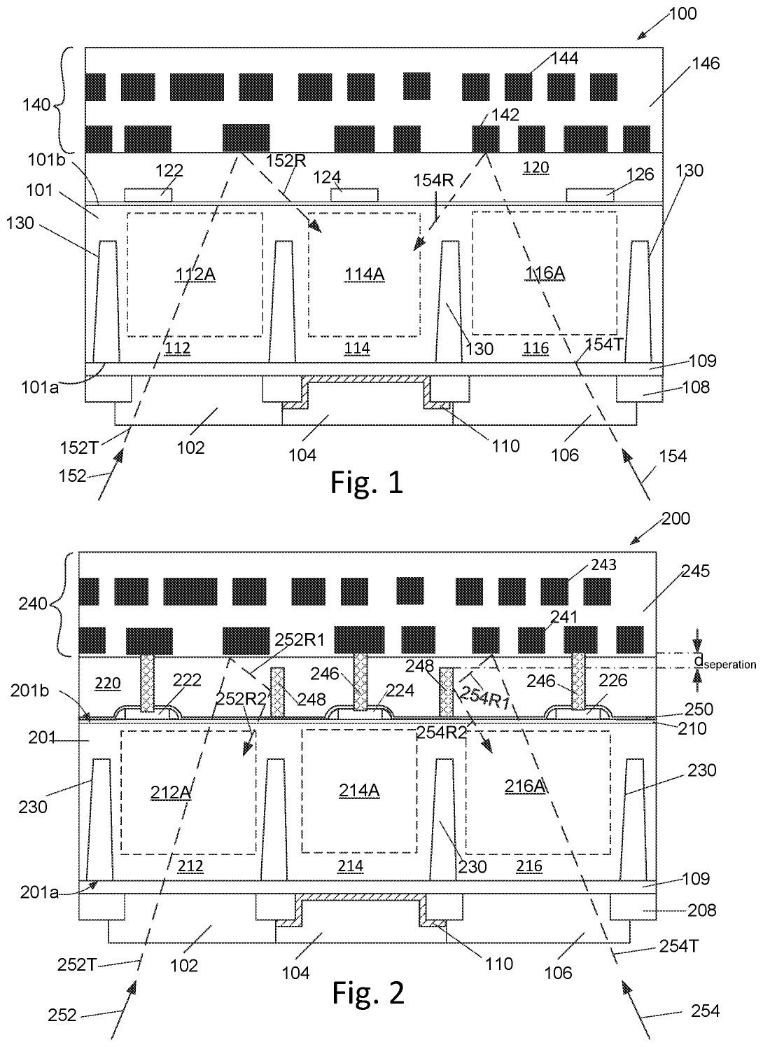

A backside-illuminated image sensor 100, as illustrated in FIG. 1, typically admits light through an array of color filters, such as filter 102, 104, 106 through a backside 101a of the image sensor semiconductor substrate 101 into an array of photodiode regions 112, 114, and 116 formed in the image sensor semiconductor substrate 101.

In embodiments, the backside-illuminated image sensor 100 includes a metal grid 108 forming a plurality of apertures aligning with photodiode regions 112, 114, and 116. Each of color filters 102, 104, 106 may be aligned to a respective photodiode region 112, 114, or 116 and within an aperture of metal grid 108. In embodiments, metal grid 108 is formed on a planarized buffer dielectric layer 109 (such as silicon oxide) on backside 101a. In embodiments, backside 101a can be referred as an illuminated side of backside-illuminated image sensor 100, and front side 101b can be referred as a non-illuminated side of backside-illuminated image sensor 100. In embodiments, photodiode regions 112 and 116 are also referred as dim or low-light photodiode sensing regions for resolving pixel data in low-light portions of the image, and photodiode regions 114 are also referred as bright-light photodiode sensing regions for resolving pixel data in bright-light portions of the image. In some embodiments, bright-light photodiode sensing regions 114 are surrounded by dim or low light photodiode sensing regions 112, 116.

In some embodiments, each of color filters 102, 104, 106 may be one of a red, blue, green, cyan, magenta, yellow, infrared, or panchromatic color filter. In some embodiments, the array of color filters 102, 104, 106 may be arranged accord to Bayer's pattern.

Each of photodiode regions 112, 114, 116 includes a respective photodiode 112A, 114A, 116A along with associated a selection, a reset, a source-follower, and a row select transistors associated with each photodiode, of which only selection transistors are shown in FIG. 1, as common in the art of image sensor arrays. Photodiodes 112A, 116A included in photodiode regions 112, 116 may be referred as large photodiodes or low-light sensing photodiodes for sensing low-level light. Photodiodes 114A included in photodiode regions 114 may be referred as small photodiodes or bright-light sensing photodiodes for sensing bright light. In some embodiments, a full well capacity of each individual photodiode 114A is smaller than a full well capacity of each of individual photodiodes 112A, 116A. Full well capacity (FWC) refers to amount of charges or electrons that a photodiode can accumulate before it reaches saturation. In other words, each of photodiode 112A or 116A may have larger charge storage capacity and able to store more photo-generated charges than photodiode 114A. In some examples, each of photodiode 112A or 116A may have a larger light exposure area than the light exposure area of neighboring small photodiode 114A.

In embodiments, one of photodiodes 112A, 116A of photodiode regions 112, 116 and adjacent photodiode 114A form a high dynamic range pixel in backside-illuminated image sensor 100.

The selection transistor may also be referred to as a transfer transistor. In one embodiment, selection transistor has a gate e.g., transfer gate 124 couples a photodiode (e.g., photodiode 114A) to a respective floating diffusion (not illustrated) and selectively transfers photo-generated charges from the photodiode (e.g., photodiode 114A) to the coupled floating diffusion. While a planar selection transistor is illustrated in FIG. 1, alternative devices may have vertical selection transistors, for example each of transfer gates 122, 124, 126 may have at least a vertical electrode extended into image sensor semiconductor substrate 101. Admitted light induces photocurrent in the photodiodes 112A, 114A, 116A of the array of photodiode regions 112, 114, and 116. The photocurrent in individual photodiodes 112A, 114A 116A of the array of photodiode regions 112, 114, and 116 is sensed through the pixel transistors (e.g., selection transistors, reset transistors, source follower transistors, row-select transistors) formed in a front side 101b of the image sensor semiconductor substrate 101. The pixel transistors are controlled, by a control circuitry, where control circuitry may be coupled to the pixel transistors through multi-layer metal interconnect structure. In operation, the selection or transfer signals, read out signals, reset signals may be outputted by the control circuitry through a multi-layer metal interconnect structure and contacts (omitted for simplicity) to the corresponding pixel transistors to drive the operation of pixel transistors. The photodiode reset signals, and image signals generated from photocurrents in the photodiodes 112A, 114A, 116A are outputted to a read-out circuitry through multi-layer metal interconnect structure 140 and contacts.

The multi-layer metal interconnect structure 140 includes first layer of metal interconnect lines 142 and second layer of metal interconnect lines 144 formed over an interlayer dielectric layer 120 (typically silicon oxide) formed on the front side 101b of the image sensor semiconductor substrate 100. The second layer of metal interconnect lines 144 may exist above the first layer of metal interconnect lines 142 and may be separated by isolation material. Contacts may electrically connect electrodes (e.g., gate electrode, source electrode, drain electrode) of pixel transistors to the corresponding sections of multi-layer metal interconnect structure 140. Contacts may be formed in the interlayer dielectric layer 120. For example, a contact may extend from a metal interconnect line in the first layer of metal interconnect lines 142 to a gate electrode of a corresponding pixel transistor such as selection transistor or transfer gate 124, to establish electrical connection therebetween. The multi-layer metal interconnect structure 140 may be embedded in an inter-metal dielectric material 146 separating and isolating adjacent layer of metal interconnect lines. The inter-metal dielectric material 146 may comprise a dielectric material such as silicon dioxide, silicon nitride, porous oxide material or low κ dielectric material. In embodiments, the interlayer dielectric layer 120 and inter-metal dielectric material 146 may be formed of same or different material.

Some bright-light photodiode sensing regions 114 of the array of photodiode regions 112, 114, and 116 are intended to respond primarily to brightly illuminated portions of an image and may in some embodiments also have neutral density filter 110 in addition to color filters 104, wherein the neutral density filter 110 reduces intensity of incident light and lower the light sensitivity of photodiode 114A; while dim light photodiode sensing regions 112, 116 intended to respond primarily to dimly illuminated portions of an image lack neutral density filters 110 and may have greater photodiode surface area than bright-light photodiode sensing regions 114. Restated, incident light directed to photodiode 114A, for example by a microlens (not illustrated) passes through color filters 104 and neutral density filter 110 before entering photodiode regions 114 and absorbed by photodiodes 114A. Incident light directed to photodiode 112A passes respective color filters 102 before entering photodiode regions 112 and absorbed by photodiodes 112A, and incident light directed to photodiodes 116A passes respective color filters 106 before entering photodiode regions 116 and absorbed by photodiodes 116A.

In many image sensor devices, an isolation trench structure 130 serves to isolate photodiodes from each other and to eliminate electrical crosstalk such as would arise if carrier pairs generated in one photodiode region (e.g., photodiode region 112A) were permitted to migrate to another photodiode region (e.g., photodiode region 114A). Isolation trench structure 130 may be in form of a trench grid surrounding each individual photodiode region in the array of photodiode regions 112, 114, and 116. In some embodiments, isolation trench structure 130 is an oxide-filled isolation trench, or an oxide-lined, metal-filled isolation trench, or a combination thereof. In some embodiments, isolation trench structure 130 is aligned with metal grid 108 in a direction that is perpendicular to front surface of the image sensor semiconductor substrate 101.

In prior devices, some incident light 152, 154 enters backside 101a of high sensitivity, dim-light photodiode sensing regions 112, 116 having optical paths 152T, 154T that extend at high angles of incidence directed toward first layer of metal interconnect lines 142; while some of incident light 152, 154 is absorbed in dim-light photodiode sensing regions 112, 114 by respective photodiodes 112A, 116A, some unabsorbed portion of incident light 152, 154 reaches first layer of metal interconnect lines 142 and is reflected or scattered along paths 152R, 154R that enter bright-light photodiode sensing regions 114, where some of the reflected light along paths 152R, 154R may be absorbed, for example by respective photodiodes 114A. This reflected light thus may induce a crosstalk signal in photodiodes 114A of bright-light photodiode sensing regions 114 affecting image quality.

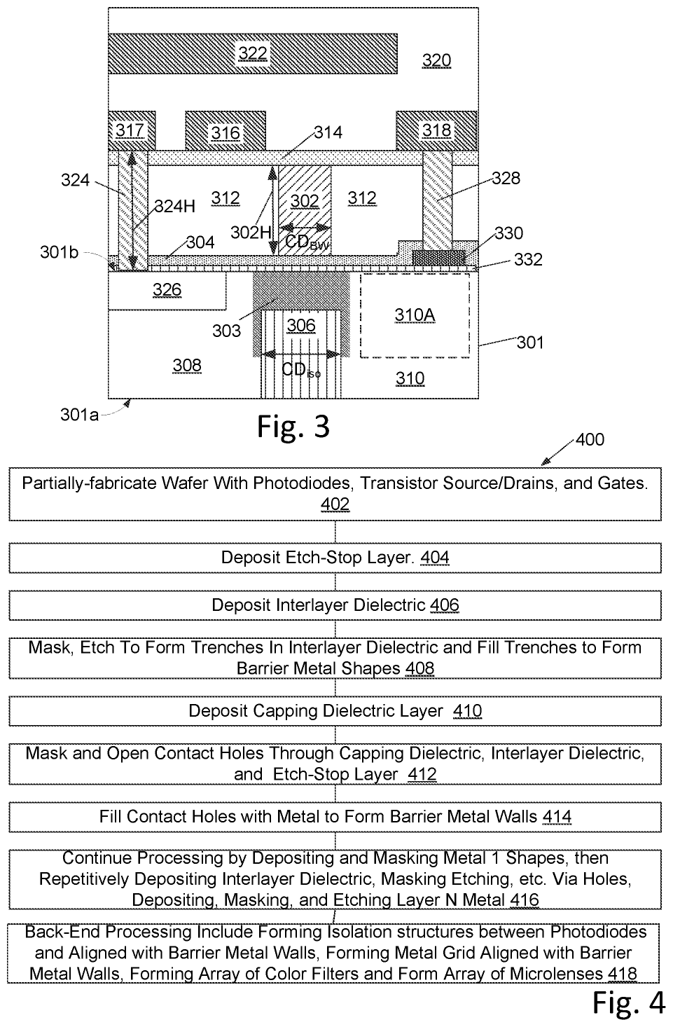

In an embodiment, backside-illuminated image sensor 200 (FIG. 2), like image sensor 100 admits light through an array of color filters, such as filter 102, 104, 106 through a backside 201a of the image sensor semiconductor substrate 201 into an array of photodiode regions 212, 214, and 216 formed in the image sensor semiconductor substrate 201. Each of photodiode regions 212, 214, and 216 includes a respective photodiode and associated selection, reset, source-follower, and row select transistors, of which only selection transistors (indicated by gate electrode 222, 224, 226) are shown in FIG. 2. Each of photodiode regions 212 include a photodiode 212A. Each of photodiode regions 214 include a photodiode 214A. Each of photodiode regions 216 include a photodiode 216A.

In embodiments, photodiode regions 212 and 216 are referred as bright-light photodiode sensing regions, and photodiode regions 214 is referred as dim or low light photodiode sensing regions. Photodiode regions 214 may be arranged to be surrounded by photodiode regions 212 and 216. In embodiments, bright-light photodiode sensing regions 214 are intended to respond primarily to brightly illuminated portions of an image, and may have neutral density filter 110 in addition to color filters 104, to reduce intensity of incident light directed to photodiode 214A; while dim or low light photodiode sensing regions 212, 216 intended to respond primarily to dimly illuminated portions of an image lack neutral density filters 110. Each of photodiodes 212A, 216A may have greater full well capacity than each of photodiodes 214A. In embodiments, each of photodiodes 212A, 216A is referred as large photodiode, and each of photodiodes 214A is referred as small photodiode.

It is observed that by forming a barrier wall 248 extending from below first layer of metal interconnect lines 242 to above isolation trench structures 230 we can optically isolate adjacent photodiodes in photodiode array of the image sensor. In one embodiment, barrier walls 248 may be formed in metal grid-like manner that formed between first layer of metal interconnect lines 242 and isolation trench 230. In embodiments, the barrier wall 248 is aligned with the isolation trench structure 230.

In the image sensor device of FIG. 1, while a majority of light photons from incident light 152, 154 entering dim-light photodiode sensing regions 112, 114 along respective optical paths 152T, 154T are absorbed there and generating carrier pairs in photodiodes 112A, some unabsorbed light reaches one or more of metal interconnect lines in the first layer of metal interconnect lines 242 and, depending on the incident angle, may reflect or scatter into adjacent bright-light photodiode sensing regions 114 causing optical crosstalk. In the image sensor device of FIG. 2, much incident light 252, 254 that enters the dim-light photodiode sensing regions 212, 216A along respective optical paths 252T, 254T, corresponding to optical paths 152T, 154T, is reflected or scattered by first layer of metal interconnect lines 242 and strikes the barrier walls 248. The barrier walls 248 can function as light shield and prevent this reflected or stray light from reaching bright-light photodiode sensing regions 214 and may further reflect or scatter some of back into the respective dim-light photodiode sensing regions 212, 216 to enhance light absorption by respective photodiodes 212A, 216A. For example, incident light 252 directed toward a photodiode region 212 may be first transmitted along optical path 252T, reflected by the first layer of metal interconnect lines 242 along optical path 252R1, and reflected or scattered by the barrier wall 248 back to the photodiode region 212 along path 252R2, thereby preventing reflected light of incident light 252 from crossing over to adjacent photodiode regions 214 to cause crosstalk. Similarly, incident light 254 directed toward a photodiode region 216 may be first transmitted along optical path 254T, reflected by the first layer of metal interconnect lines 242 along optical path 254R1, and reflected or scattered by the barrier wall 248 back to the photodiode region 212 along path 254R2, thereby preventing reflected light of incident light 254 from crossing over to adjacent photodiode regions 214 to cause crosstalk.

Those photons that are reflected or scattered back into the dim-light photodiode sensing regions may be further absorbed by respective photodiodes 212A, 216A, thereby enhancing sensitivity of photodiodes 212A, 216A and are thereby prevented from generating photocurrent in bright-light photodiode sensing region of photodiodes (small photodiodes) 214A. Optical crosstalk between the dim-light, photodiode regions 212, 216 and adjacent bright-light photodiode sensing regions 214 is thereby reduced. Shapes in FIG. 2 having reference numbers that duplicate reference numbers in FIG. 1 have similar function to corresponding shapes in FIG. 1.

Admitted incident light induces photocurrent in photodiodes 212A, 214A, 216A of the array of photodiode region 212, 214, 216. The photocurrents in photodiodes 212A, 214A, 216A are sensed through pixel transistors formed on a frontside 201b of the image sensor semiconductor substrate 201. The pixel transistors on the front side 201b of the image sensor semiconductor substrate 201 are controlled by a control circuit of the image sensor 200. The gate electrodes of pixel transistors may be formed on a gate insulation layer 210 formed on the front side 201b of the image sensor semiconductor substrate 201. In one embodiment, the photodiodes reset signals, photodiode selection signals, and electronic signals generated from photocurrents in the corresponding photodiodes 212A, 214A, 216A, are coupled to and from the photodiodes 212A, 214A, 216A through multi-layer metal interconnect structure 240.

The multi-layer metal interconnect structure 240 includes a first layer of metal interconnect lines 241 and a second layer of metal interconnect lines 243, are formed over an interlayer dielectric layer 220 (e.g., silicon oxide) formed on the front side 201b of the image sensor semiconductor substrate 200. The second layer of metal interconnect lines 243 lies above the first layer of metal interconnect lines 241. Contacts 246 may electrically connect electrodes (e.g., gate electrode, source electrode, drain electrode) of pixel transistors (e.g., selection transistors, reset transistors, source-follower transistors, row-select transistors) to the corresponding metal interconnect lines of first layer of metal interconnect lines 241. Contacts 246 may be formed in the interlayer dielectric layer 220. For example, a contact 246 may extend from a metal interconnect line in the first layer of metal interconnect lines 241 to a gate electrode (e.g., gate electrode 224) of the corresponding selection transistor to establish electrical connection therebetween. The multi-layer metal interconnect structure 240 may be embedded in an inter-metal dielectric material 245 providing isolation between each layer of metal lines. The inter-metal dielectric material 245 may comprise as silicon dioxide, silicon nitride, porous oxide material or low κ dielectric material. In embodiments, the interlayer dielectric layer 220 and inter-metal dielectric material 247 may be formed of same or different material.

In one embodiment, the control circuitry may be coupled to the pixel transistors through contacts 246 and first layer of metal lines 241 of multi-layer metal interconnect structure 240 formed over an interlayer dielectric 220 formed on the front side 101b of the image sensor semiconductor substrate 201. The first layer of metal interconnect lines 241 and the second layer of metal interconnect lines 243 may include metal interconnect lines that couple photodiodes 212A, 214A, 216A to reset, gate electrodes 222, 224, 226 of selection transistors through contacts 246 and source follower transistors and metal interconnect lines that interface to additional circuitry (not shown) of the image sensor external to the array of photodiodes. Additional insulating oxide 118 layers and metal interconnect lines 144, 322 may exist above the first layer metal interconnect lines 142.

In embodiments, contacts 246 and barrier wall 248 are separated from each other and electrically isolated from each other by the interlayer dielectric 220. In some embodiments, contacts 246 and barrier wall 248 are formed of same material and in same process. In some embodiments, contacts 246 extend through an etch-stop layer 250 formed on gate insulation layer 210 to contact electrodes of pixel transistors such gate electrode, source/drain electrodes, and the barrier wall 248 is formed on the etch-stop layer 250 and does not contact material underlying the etch-stop layer 250.

Isolation trench structure 230, an example of isolation trench structure 130, isolates adjacent photodiodes 212A, 214A, 216A from each other and eliminates electrical and/or optical crosstalk as would arise if carrier pairs generated in one photodiode region 212A migrated to another adjacent photodiode region 214A before being collected as photocurrent in respective photodiodes of the array. In embodiments, isolation trench structure 230 may form a grid structure in the image sensor semiconductor substrate 201 surrounding photodiode regions 212, 214, 216. In some embodiments, a depth of isolation trench structure 230 is the substantially the same as the thickness of image sensor semiconductor substrate 201. In some embodiments, a depth of isolation trenches 230 is the less than the thickness of image sensor semiconductor substrate 201. In embodiments, a thickness of image sensor semiconductor substrate 201 ranges from 2.5 μm to 7 μm, and the depth that isolation trenches 230 extend into image sensor semiconductor substrate 201 may range from 1 μm to 5 μm. In embodiments, isolation trench structure 230 may be an oxide-filled isolation trench structure or a metal-filled isolation trench structure.

In embodiments, barrier wall 248 is aligned with at least part of isolation trench structure 230 in a direction perpendicular to front side 201b surface. In some embodiments, barrier wall 248 includes multiple disconnected wall segments and each wall segment is vertically aligned with the respective isolation trench structure 230, and arranged between bright light photodiode sensing regions 214 and adjacent dim or low light photodiode sensing regions 212, 216. Barrier wall 248 may be further aligned with metal grid 208. In some embodiments, barrier wall 248 may form a plurality of front side apertures that are aligned photodiode regions 214 and surround photodiode regions 214 by at least three sides. The plurality of front side apertures is aligned with apertures defined by metal grid 208 formed on a planarized buffer dielectric layer 209 (such as silicon oxide) on backside 201a.

In embodiments barrier wall 248 and isolation trench structure 230 are separated and electrically isolated. In embodiments, there is a vertical spacing dₛₑₚₑᵣₐₜᵢₒₙ between barrier wall 248 and first layer of metal interconnect lines 241, wherein the vertical spacing dₛₑₚₑᵣₐₜᵢₒₙ may range twenty to forty nanometers.

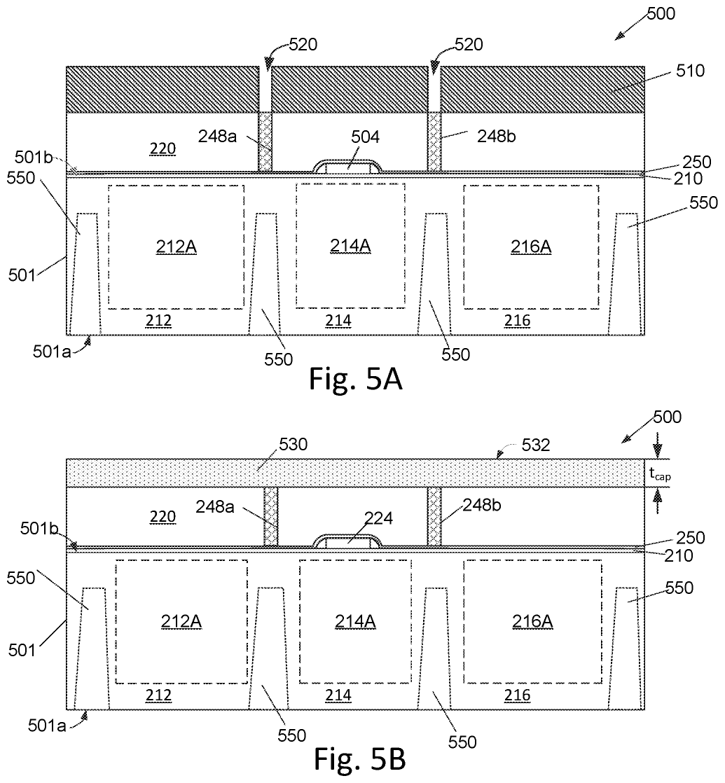

A barrier wall 302 of an embodiment is illustrated in cross section in greater detail in FIG. 3. Immediately beneath the barrier wall 302 is an etch-stop layer 304 that separates barrier wall 302 from the isolation trench structure 306 and provides isolation between photodiode region 310 containing photodiode 310A and transistor region 308. In embodiments, etch-stop layer 304 comprises silicon oxynitride or another dielectric material having etch selectivity over underlying gate insulation layer 332 and semiconductor substrate 301 (e.g., silicon substrate). In embodiments, isolation trench structure 306 is an oxide-filled isolations structures formed from backside of semiconductor substrate 301. In one embodiment, the isolation trench structure 306 extends from backside 301a of semiconductor substrate 301 to the front side 301b of semiconductor substrate 301 forming backside full isolation structure, wherein the front side 301b is opposite to backside 301a. In one embodiment, the isolation trench structure 306 extends a depth from backside 301a of semiconductor substrate 301 toward the front side 301b of semiconductor substrate 301 that is less than the thickness of semiconductor substrate 301 forming a partial backside isolation structure. In embodiments, barrier wall 302 is not in direct contact with isolation trench structure 306 as there is at least an etch-stop layer 304 formed in between barrier wall 302 and isolation trench structure 306.

In the illustrated embodiment, barrier wall 302 is embedded in an interlayer dielectric layer 312 and capped by an additional dielectric material 314 that prevents it from contacting first layer metal interconnect 316, 317, 318. Dielectric material (e.g., oxide material) 314 may electrically isolate barrier wall 302 from first layer metal interconnect 316. 317, 318. Barrier wall 302 is further separated and electrically isolated form contacts 324, 328 by the interlayer dielectric layer 312. The dielectric material 314 may have sufficient thickness (e.g., 20-40 nm) to provide electrical isolation between barrier wall 302 and first layer metal interconnect 316, 317, 318. In embodiments, a wall width CD_{BW} of barrier wall 320 along a first direction parallel to a front side 301b surface of semiconductors substrate 301 is smaller than an isolation width CD_{ISO} of isolation trench structure 306 along the first direction. In one embodiment, additional dielectric material 314 is omitted to enable barrier wall 302 to electrically connect first layer metal interconnect 316, 317, 318 to a ground reference source, thereby grounding barrier wall 302 and provide charge discharge path for photon-induced charges that may be accumulated on barrier wall 302.

In particular embodiments, barrier walls 302 are aligned with, and positioned directly over, isolation trench structures 306 that are at least partially disposed in an isolation well 303 having conductive type the same as semiconductor substrate 301 but opposite to a conductive type of photodiode 310A. First layer metal interconnect lines 316, 317, 318 is embedded within yet more dielectric material 320, as is second layer metal interconnect line 322. Metal-filled contacts 324, typically square or circular in top plan view, may at various locations extend from first layer metal interconnect line 317 through additional dielectric oxide 314 and etch-stop layer 304 to source/drain implanted regions 326 of transistors in semiconductor substrate 301 having transistor region 308 and photodiode region 310, and metal-filled contacts 328, may at various locations extend from corresponding first layer metal interconnect lines through additional dielectric oxide 314 and etch-stop layer 304 to silicided polysilicon gates 330 (e.g., gate electrode for selection transistor that couple photodiode 310A to a floating diffusion (not illustrated). While metal-filled contacts 324, 328 are typically square or circular in top plan view, metal walls 302 are typically formed as long, narrow, strips in top plan view, the long, narrow, strips surrounding all or major portions of each photodiode region of an array of photodiode regions; the more completely the long, narrow, strips surround each photodiode region of the array, the more effective the strips of metal wall are at reducing optical crosstalk between adjacent photodiodes of the image sensor. In particular embodiments, the long, narrow, strips have a length to width ratio greater than or equal to four providing sufficient light block material thickness, and sufficient wall length to block stray light rays (for example ray 252R1 of FIG. 2) reflected from first layer metal interconnect lines 316, 318 by reflection and/or absorption, thereby shielding photodiode region 310 from such stray light and reducing crosstalk. In embodiments, metal-filled contacts 324, 328, and barrier wall 302 can be formed of tungsten.

In embodiments, metal-filled contacts 324, 328 and barrier wall 302 can be formed of different materials, for example, metal-filled contacts 324, 328 may be formed of tungsten, while barrier walls 302 are formed of aluminum. For another example, metal-filled contacts 324, 328 may be formed of cooper or non-tungsten metal alloy, barrier walls 302 are formed of tungsten. In some embodiments, a height of a metal-filled contact 324 or 328 is greater than a height of barrier wall 302 as depicted in FIG. 3. For example, a height 324H of a metal-filled contact 324 is greater than a height 302H of barrier wall 302.

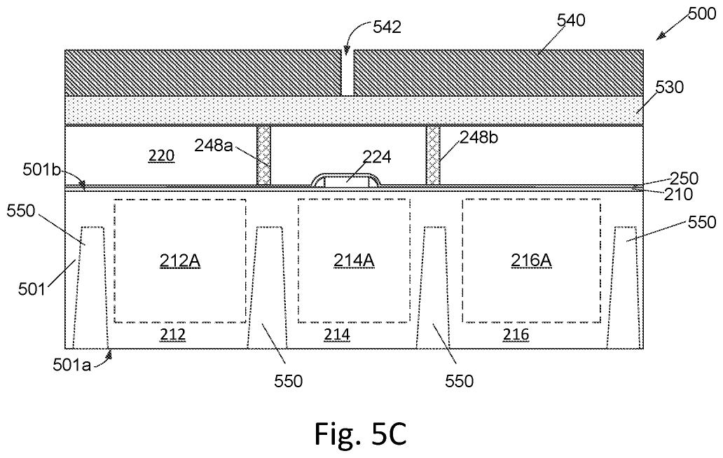

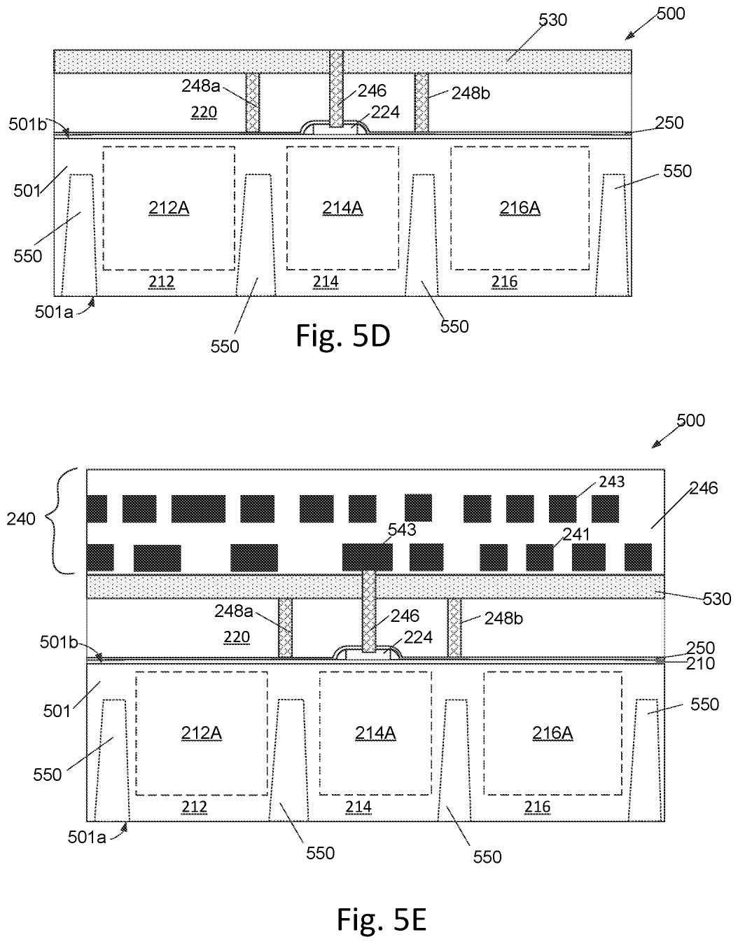

The structure illustrated in FIGS. 2 and 3 may be formed according to a method 400 (FIG. 4 and FIGS. 5A-5F). Fabrication of barrier walls on a wafer begins 402 with a partially-fabricated semiconductor substrate 501 having photodiodes, floating diffusion, and source-drain regions formed therein, for example by ion implantation. The partially or semi-fabricated semiconductor substrate 501 may have a gate oxide layer grown on a front side thereof forming gate insulation layer by thermal oxidation process, and a silicided polysilicon gate material formed by deposition and etching to form gate electrodes on gate insulation layer 210. In some embodiments, the semiconductor substrate 501 is a single-crystal silicon substrate. In embodiment, the semiconductor substrate 501 may further have shallow isolation structures formed extending from front side 501b into semiconductor substrate 501.

An etch-stop layer is then deposited 404 over the silicided gate electrodes and the front side surface of semi-fabricated semiconductor substrate. In embodiments, the etch-stop layer 250 or 304 covers the silicided gate electrodes entirely. In embodiments, the etch-stop layer 250 or 304 may be formed on the gate insulation layer 210 providing etching protection to underlying gate insulation layer 210 and front side 501b surface of the semiconductor substrate 501.

In embodiments, etch-stop layer 250 comprises material having etching selectivity over underlying gate insulation layer 210 and the semiconductor substrate (e.g., silicon substrate). In an embodiment etch-stop layer 250 is a layer of silicon oxynitride. Atop the etch-stop layer 250 is deposited 406 an interlayer dielectric encapsulating electrical component (e.g., gate electrodes) formed on the front side 501b surface of semiconductor substrate 501. In an embodiment, the interlayer dielectric is a dielectric oxide 220 formed from tetraethoxysilane and deposited on the front side 501b surface of semiconductor substrate 501 by chemical vapor deposition. Next, a masking and etching 408 operation forms trenches that extend through the interlayer dielectric oxide 220 and land on the etch stop layer 250. For example, a first mask 510 patterned is deposited on the interlayer dielectric 220 and follow by etching process to form trenches 520 extended through interlayer dielectric 220 and landed on the etch-stop layer 250 as depicted in FIG. 5A. The etching 408 to from trenches 520 is controlled to stop at the etch-stop layer 250, for example by end-point detection. The etching is followed by filling 408 the trenches with metal material to form the barrier walls 248a, 248b. In embodiments, barrier wall 248a is formed on front side 501b between photodiode region 212 and photodiode region 214, and barrier wall 248b is formed on front side 501b between photodiode region 214 and photodiode region 216. In an embodiment, the metal with which the trenches for barrier walls 248a, 248b are filled is tungsten, or aluminum.

In embodiments, a capping dielectric layer is deposited 410 and the device surface is replanarized with a chemical-mechanical polish. In embodiments, the capping layer is formed of oxide-based material such as silicon oxide, and formed on interlayer dielectric by chemical vapor deposition. For example, a capping layer 530 is deposited on interlayer dielectric 220 and with its upper surface 532 planarized as illustrated in FIG. 5B. The capping layer 530 is deposited to embed the barrier walls 248a, 248b in the interlayer dielectric 220 and electrically isolated barrier wall 248a, 248b from later-formed first layer metal interconnect of a multi-layer metal interconnect structure. The capping layer 530 may have a thickness T_{cap} that range from twenty nanometers to forty nanometers. In one embodiment, deposition of the capping dielectric layer is omitted to enable each of barrier walls 248a, 248b to electrically connect later-formed first layer metal interconnect to a ground reference source, thereby grounding barrier walls 248a, 248b and provide charge discharge path for photon-induced charges that may be accumulated on barrier walls 248a, 248b.

A masking and etching operation 412 is then performed to open a plurality of contact holes through the capping layer of dielectric material, the interlayer dielectric, and the etch-stop layer to the silicon surface or silicided polysilicon surface. The contact holes are filled 414 with metal to form contacts, in embodiments, the contact holes are filled with tungsten, aluminum, cooper, or another metal alloy. For example, as illustrated in FIGS. 5C-5D, a second mask 540 is deposited on the capping layer 530 with trench openings 542 for contact holes that corresponding to contacts 246. Each of contacts 246 extends through the capping layer 530 of dielectric material, the interlayer dielectric 220, and the etch-stop layer 250 to contact elements of pixel circuitries including gate electrodes 224, source/drain electrodes 326), or ground electrodes (not shown).

The process then concludes with deposition and etching 416 of first layer metal interconnect lines of multi-layer metal interconnect structure, then repetitively executing a sequence of depositing interlayer dielectric, masking and etching via holes, and depositing, masking, and etching each successive metal interconnect layer. After metal layers are deposited, further back-end processing 418 may be performed for backside-illuminated image sensors, including deposition of a passivation oxide atop the wafer's front side, wafer thinning, isolation trench structures, metal grid and light-attenuating filters, light-attenuating or natural density filters, deposition of color filter, and an array of microlenses on the backside of the wafer.

For example, as illustrated in FIG. 5E, a first layer metal interconnect 241 and a second-layer metal interconnect 243 embedded in inter-metal dielectric layer 247 is formed on the capping layer 530. Metal interconnect segment (e.g., metal segment 543) of first layer metal interconnect 241 is connected to the previously formed contacts 246. Although two layers of metal interconnect are illustrated herein, however it is appreciated that the number of layer metal interconnected formed is based on requirement for signal routing and may include more or fewer metal interconnect layers.

After completion of front-end of process, semiconductor substrate 501 can be flipped over to its backside 501a and further back-end processing performed as illustrated in FIG. 5F. Isolation trench structures 550, is an example of isolation trench structure 130, 230, 306 formed between adjacent photodiode regions 212, 214, 216, and aligned with barrier wall 248a, 248b. Isolation trench structure 550 may extend from backside 501a of the semiconductor substrate 501 into the semiconductor substrate 501 and filled with dielectric material such as oxide-based material or metal material such as tungsten or aluminum, or a combination of oxide-based material and metal material. A buffer layer 555 can be further deposited on backside 501a of semiconductor substrate 501. A chemical mechanical polishing process may be applied thereafter to planarize buffer layer 555 for subsequent processing. Next, metal deposition, mask and etching to form metal grid 560 that defines a plurality of apertures aligned with each individual photodiode regions 212, 214, 216 on buffer layer 555. The metal grid 560 may be formed on backside 501a with alignment to barrier walls 248a, 248b. For example, the metal grid 560 may be vertically aligned with barrier wall 248a, 248b. Optionally, neutral density filter 570 is deposited in the metal grid 560 defined apertures that is aligned to dim or low light photodiode sensing region 214 to cover the light sensing area of photodiode regions 214 and reduce light sensitivity of photodiodes 214A. Subsequently, color filter material in the plurality of apertures to form array of color filters 582, 584, 586. Thereafter, microlens material (e.g., polymer) is deposited to from array of microlenses 592, 594, 596 aligned with respective photodiode regions 212, 214, 216.

It is appreciated, method 400 may include more or fewer step, for example, some processing blocks can be combined or omitted based on processing needs. In some embodiments, method 400 is altered such that trenches for barrier wall 408 and contact holes are formed at the same time and filled with same material (such as tungsten) to form barrier walls and contacts, while deposition 410 of capping dielectric layer can be skipped for processing simplification and cost reduction. The barrier walls, like contacts, may further contact and electrically connect to subsequently formed first layer of metal interconnect line, for example to receive a ground voltage.

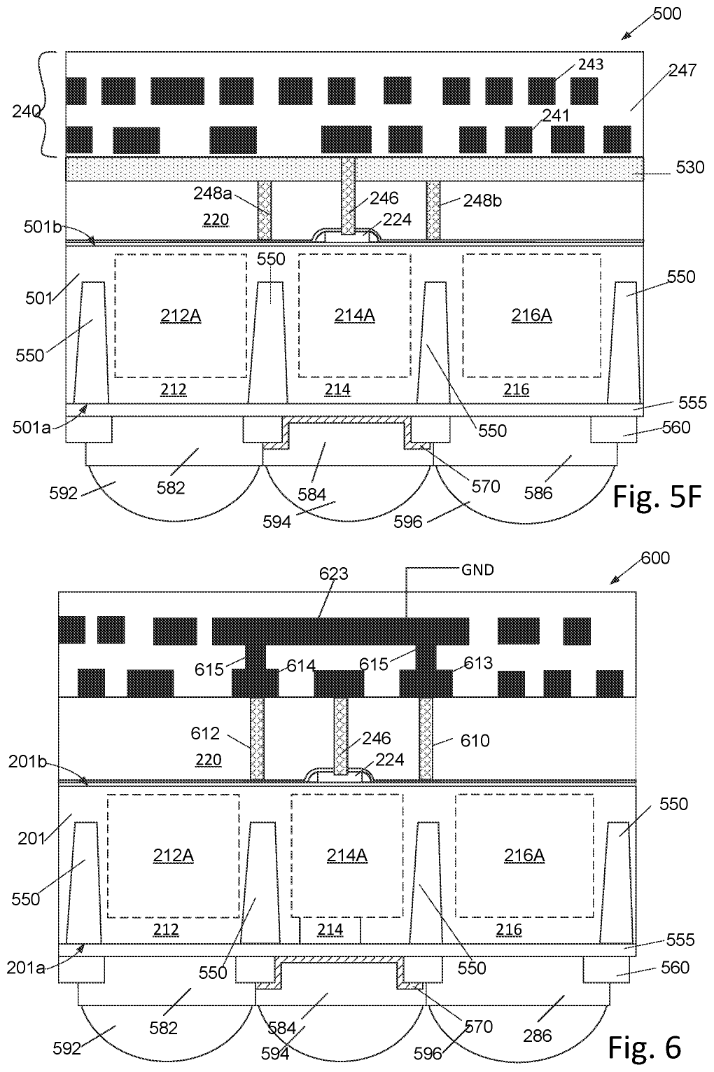

In embodiments, the barrier walls are grounded through first layer metal connection to discharge accumulated photo-induced electrons through ground lines. As shown in FIG. 6, barrier walls 610, 612 are formed extended through interlayer dielectric 220 similar to contacts 246 connecting to first layer of metal interconnect lines. In one embodiment, barrier walls 610, 612 connects electrically to a ground line through second layer metal interconnect lines 623 and metal interconnect lines 613, 614, contact vias 615 forming to receive ground reference voltage and providing discharge path.

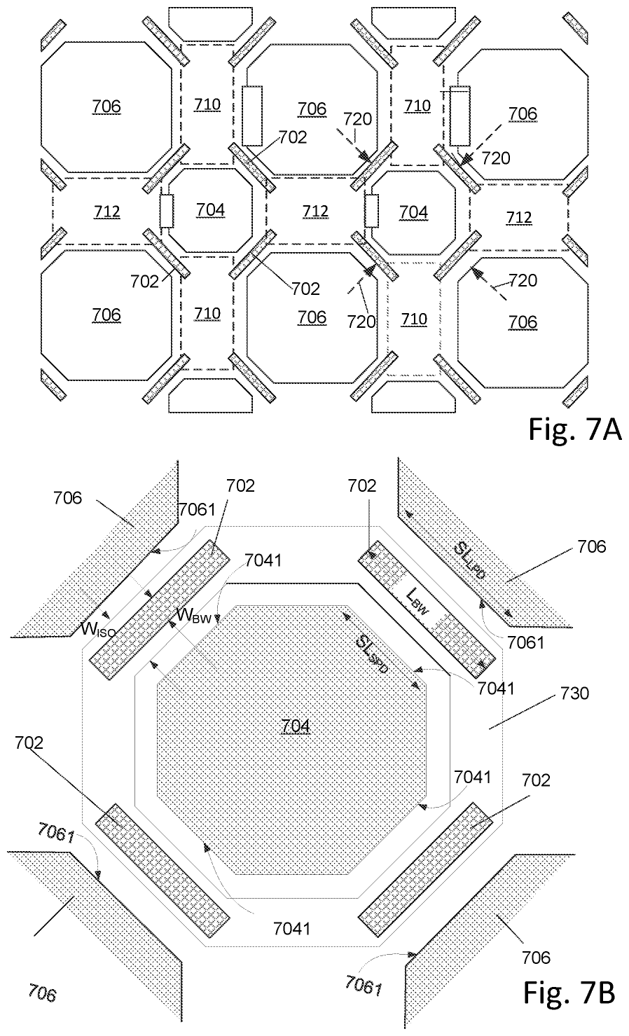

In an exemplary layout (FIG. 7A) barrier walls 702 are disposed between small photodiodes 704 and adjacent large photodiodes 706 of the backside-illuminated image sensor.

As shown in FIG. 7A, a small photodiode 704 may be surrounded by four large photodiodes 706, barrier walls 702, which is an example of barrier walls 248, 248a, b, 302. Barrier walls 702 are arranged in between the respective small photodiode 704 and each of four large photodiodes 706 to block light 720 intended for the adjacent large photodiodes 706 that is reflected by first layer metal interconnected from crosstalk over to small photodiode 704 through absorption and/or reflection. In embodiments, each of small photodiodes 704 has a first full well capacity that is smaller than a second full well capacity of each of adjacent large photodiodes 706 and stores less photo-generated charges than each individual large photodiode 706. Alternative, each of large photodiodes 706 may have larger light exposure area than the light exposure area of each neighboring small photodiode 704.

Barrier walls 702 may be arranged to surround each of small photodiodes 706 or photodiodes of a first size. Multiple disconnected barrier walls 702 (e.g., four barrier walls 702 illustrated in 7A) may collectively surround one of small photodiodes 704 and define front side apertures aligned with a light sensing area of respective small photodiode 704, of which they surround.

In some embodiments, the dimensions (width and/or length) of each barrier wall 702 are configured to have sufficient separation from contacts formed to connect gate electrodes and source/drain electrodes in transistor region 710, 722 based on processing design rule. Transistor region 710 may include one or more pixel transistors associated with small photodiode. Transistor region 712 may include one or more pixel transistors associated with large photodiode 706, or photodiodes of a second size.

Multiple, disconnected, barrier walls 702 are placed above isolation trench structures 730 and align with isolation trench structures 730. Isolation trench structures 730, which is an example of isolation trench structure 130, 230, 306, 550 may be arranged to surround each of large and small photodiodes 704, 706. In a zoom-in view on arrangement of barrier walls 702 in FIG. 7B, the isolation trench structure 730 surrounds a small photodiode 704 and the shape of isolation trench structure 730 may be conformal to the shape of small photodiode 704. Although the small photodiode 704 or large photodiode 706 illustrated is of octagonal shaped, however, it should be appreciated the shape of small photodiode 704 can include other suitable polygonal shape such as square, rectangular, triangular based on pixel layout needs. The barrier walls 702 may be arranged to align with isolation trench structure 730.

In embodiments, each of barrier walls 702 has a wall width less than the trench width of isolation trench structure 730. For example, a width W_{BW} of a barrier wall 702 is less than a width W_{ISO} of a respective isolation trench structure 730. In further embodiment, wall width W_{BW} of each barrier wall 702 can be at least forty-five nanometers to provide sufficient light block or absorption effect and width W_{ISO} of isolation trench structure 730 can be at least a hundred nanometers. In embodiments, a ratio between the wall length L_{BW} to the wall width W_{BW} is greater than or equal to four. In embodiments, each of the barrier walls 702 has a wall length L_{BW} greater than the edge length of adjacent octagonal-shaped small photodiode 704 and octagonal-shaped large photodiode 706. For example, the wall length L_{BW} of barrier wall 702 arranged between a small photodiode 704 and a large photodiode 706 is greater than a first edge length SL_{SPD} of Side Edge 7041 of Small Photodiode 704 and a Second Edge Length SL_{LPD} of Side edge 7061 of large photodiode 706 so as to effectively absorb or reflect any first layer metal reflected light within region of large photodiode 706 and thereby preventing that reflected light from crossing over to a region containing small photodiode 704 and thereby preventing crosstalk.

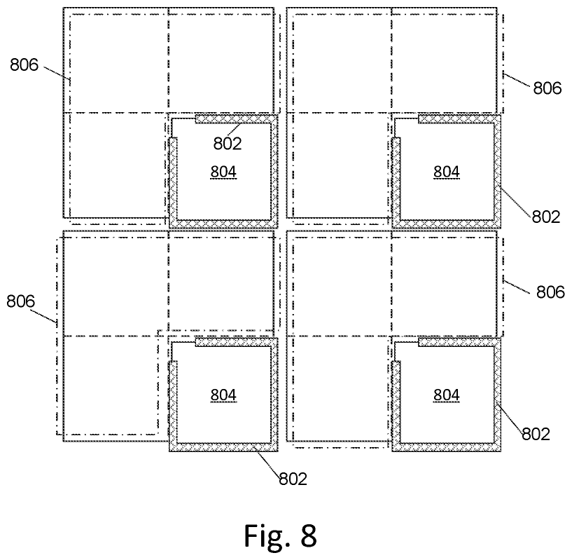

In another exemplary layout (FIG. 8) for a pixel array of a backside-illuminated image sensor. The pixel array includes a plurality of unit pixel cells, where each pixel cell includes four photodiodes (also refers as four-shared pixel cell), wherein the four photodiodes may share a floating diffusion region and three of which is configured as a large photodiode 806 and one is configured as a small photodiode 804 having smaller full well capacity and/or lower light sensitivity relative to large photodiode 806. Each of small photodiodes 804 is surrounded by large photodiodes 806 in the pixel array. Barrier walls 802 is disposed to surrounded small photodiodes 804 by at least four sides to provide optical isolation between small photodiodes 804 and adjacent large photodiodes 806 of a backside-illuminated image sensor. In embodiments, a barrier wall 802 partially enclose the small photodiode to enable placement of associated pixel component e.g., gate electrode of selection transistor and associated contact.

### Combinations

The features herein disclosed can be combined in many ways. Among feature combinations anticipated by the inventors are:

A backside-illuminated image sensor designated A, the image sensor of the type comprising an array of photodiodes formed in a semiconductor substrate, the photodiodes electrically isolated from each other by isolation structures, an interlayer dielectric disposed between a first layer of metal interconnect and the semiconductor substrate. The image sensor includes a barrier metal wall disposed in the interlayer dielectric between the isolation structures and the first layer of metal interconnect, the barrier metal wall being aligned with the isolation structures and disposed between the isolation structures and first layer of metal interconnect.

A backside-illuminated image sensor designated AA including the image sensor designated A wherein the barrier metal wall comprises tungsten.

A backside-illuminated image sensor designated AB including the image sensor designated A or AA wherein the barrier metal wall comprises mask-defined shapes having a length to width ratio greater than or equal to four.

A backside-illuminated image sensor designated AC including the image sensor designated A, AB or AA wherein the barrier metal wall is separated from the isolation structures disposed in the semiconductor substrate by an etch-stop layer comprising material having etching selectivity over the semiconductor substrate.

A backside-illuminated image sensor designated AD including the image sensor designated AC wherein the etch-stop layer comprises silicon oxynitride.

A backside-illuminated image sensor designated AE including the image sensor designated A, AB, AC, AD, or AA, the barrier metal wall being capped by a dielectric layer disposed between the first layer of metal interconnect and the interlayer dielectric, wherein the barrier metal wall is electrically isolated from the first layer of metal interconnect.

A backside-illuminated image sensor designated AF including the image sensor designated A, AB, AC, AD, or AE or AA further including a metal grid defining a plurality of apertures aligned with a plurality of photodiodes, the metal grid being aligned with the barrier metal wall; a plurality of neutral-density filters in a first group of apertures that are aligned with a first group of photodiodes and wherein a second group of photodiodes lacks neutral-density filters, and a plurality of color filters in the first group of apertures and a second group of apertures that is aligned with the second group of photodiodes, wherein the metal grid separates adjacent color filters.

A backside-illuminated image sensor designated AG including the image sensor designated A, AB, AC, AD, AE, AF or AA, wherein the barrier metal wall is disposed between a first photodiode of the first group of photodiodes and a second photodiode of the second group of photodiodes adjacent to the first photodiode.

A backside-illuminated image sensor designated AH including the image sensor designated AF or AG, wherein the barrier metal wall partially surrounds the first photodiode of the first group of photodiodes.

A backside-illuminated image sensor designated AJ including the image sensor designated A, AB, AC, AD, AE, AF, AG, AH, or AA, wherein the barrier metal wall is electrically connected to the first layer of metal interconnect to receive a ground voltage.

A method designated B of fabricating a backside-illuminated image sensor includes forming a plurality of photodiodes and source-drain regions in a semiconductor substrate; forming at least one gate electrode on a front side surface of the semiconductor substrate depositing an etch-stop layer over the at least one gate electrode on the front side surface of the semiconductor substrate; depositing an interlayer dielectric on the etch-stop layer; forming one or more trenches through the interlayer dielectric and extending to but not through the etch-stop layer, wherein each of the one or more trenches is formed between a first photodiode and a second photodiode of the plurality of photodiodes; and filling the one or more trenches with metal to form one or more barrier metal walls.

A method designated BA including the method designated B, further including forming a first layer of metal interconnect on the interlayer dielectric after filling the or more trenches with metal.

A method designated BB including the method designated B or BA, wherein, after filling the one or more trenches with metal, the method further includes depositing a capping layer directly on the interlayer dielectric to embed the one or more barrier metal walls and separating the one or more barrier metal walls from the first layer of metal interconnect.

A method designated BC including the method designated B, BB, or BA, further includes masking and etching to open a contact hole through the interlayer dielectric and adjacent to the one or more barrier metal walls, and through the etch-stop layer to a surface of the at least one gate electrode; and depositing metal material filling the contact hole to form a contact to electrically connect the at least one gate electrode to a first metal interconnect of the first layer of metal interconnect. The method requires the one or more barrier metal walls and the contact be separated by interlayer dielectric and electrically isolated from each other.

A method designated BD including the method designated B, BB, BC, or BA, where the interlayer dielectric is a dielectric oxide formed from tetraethoxysilane by chemical vapor deposition, and the etch-stop layer is a layer of silicon oxynitride deposited by chemical vapor deposition.

A method designated BE including the method designated B, BB, BC, BD, or BA, where the metal with which the trenches are filled is tungsten.

A method designated BF including the method designated B, BB, BC, BD, BE or BA, further includes: forming an isolation structure from a backside surface of the semiconductor substrate opposite to the front side surface between the first photodiode and the second photodiode, wherein the isolations structure is aligned with the one or more barrier metal walls; forming a metal grid that defines a first aperture aligned with the first photodiode and a second aperture aligned with the second photodiode on the backside surface of the semiconductor substrate, wherein the metal grid is aligned with the one or more barrier metal walls; depositing a neutral-density filter in the first aperture aligning with the first photodiode; and depositing color filter material into the first aperture on the neutral-density filter and into the second aperture aligned with the second photodiode.

A method designated BG including the method designated B, BB, BC, BD, BE, BF or BA, wherein the first photodiode is of a first size, the first size being smaller than a size, the second photodiode being of the second size.

A method designated BH including the method designated B, BB, BC, BD, BE, BF, BG, or BA, wherein the process of forming the plurality of photodiodes further includes forming a third photodiode, a fourth photodiode and a fifth photodiode, wherein the second, the third photodiode, the fourth photodiode and the fifth photodiode surround the first photodiode; wherein each of third photodiode, the fourth photodiode and the fifth photodiode are of the second size.

A method designated BJ including the method designated B, BB, BC, BD, BE, BF, BG, BH, or BA, wherein forming one or more trenches through the interlayer dielectric comprises forming a first trench between the first photodiode and the second photodiode, a second trench between the first photodiode and third photodiode, a third trench between the first photodiode and fourth photodiode, and a fourth trench between the first photodiode and fifth photodiode; and wherein filling the one or more trenches with metal comprises filling the first, second, third, and fourth trenches to form a first barrier metal wall between the first photodiode and the second photodiode, a second barrier metal wall between the first photodiode and third photodiode, a third barrier wall between the first photodiode and fourth photodiode, and a fourth barrier metal wall between the first photodiode and fifth photodiode.

Changes may be made in the above methods and systems without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

What is claimed is:

1. A backside-illuminated image sensor of the type comprising an array of photodiodes formed in a semiconductor substrate, the photodiodes electrically isolated from each other by isolation structures, an interlayer dielectric disposed between a first layer of metal interconnect and the semiconductor substrate; wherein an improvement comprises:
a barrier metal wall disposed in the interlayer dielectric between the isolation structures and the first layer of metal interconnect, the barrier metal wall being aligned with the isolation structures and disposed between the isolation structures and the first layer of metal interconnect.

2. The backside-illuminated image sensor of claim 1 wherein the barrier metal wall comprises tungsten.

3. The backside-illuminated image sensor of claim 1 wherein the barrier metal wall comprises mask-defined shapes having a length to width ratio greater than or equal to four.

4. The backside-illuminated image sensor of claim 1 wherein the barrier metal wall is separated from the isolation structures disposed in the semiconductor substrate by an etch-stop layer comprising material having etching selectivity over the semiconductor substrate.

5. The backside-illuminated image sensor of claim 4 wherein the etch-stop layer comprises silicon oxynitride.

6. The backside-illuminated image sensor of claim 1, the barrier metal wall being capped by a dielectric layer disposed between the first layer of metal interconnect and the interlayer dielectric, wherein the barrier metal wall is electrically isolated from the first layer of metal interconnect.

7. The backside-illuminated image sensor of claim 6 further comprising:
a metal grid defining a plurality of apertures aligned with a plurality of photodiodes, the metal grid being aligned with the barrier metal wall;
a plurality of neutral-density filters in a first group of apertures that are aligned with a first group of photodiodes and wherein a second group of photodiodes lacks neutral-density filters, and
a plurality of color filters in the first group of apertures and a second group of apertures that is aligned with the second group of photodiodes, wherein the metal grid separates adjacent color filters.

8. The backside-illuminated image sensor of claim 7, wherein the barrier metal wall is disposed between a first photodiode of the first group of photodiodes and a second photodiode of the second group of photodiodes adjacent to the first photodiode.

9. The backside-illuminated image sensor of claim 8, wherein the barrier metal wall partially surrounds the first photodiode of the first group of photodiodes.

10. The backside-illuminated image sensor of claim 1, wherein the barrier metal wall is electrically connected to the first layer of metal interconnect to receive a ground voltage.

11. A method of fabricating a backside-illuminated image sensor comprising:
forming a plurality of photodiodes and source-drain regions in a semiconductor substrate;
forming at least one gate electrode on a front side surface of the semiconductor substrate
depositing an etch-stop layer over the at least one gate electrode on the front side surface of the semiconductor substrate;
depositing an interlayer dielectric on the etch-stop layer;
forming one or more trenches through the interlayer dielectric and extending to but not through the etch-stop layer, wherein each of the one or more trenches is formed between a first photodiode and a second photodiode of the plurality of photodiodes; and
filling the one or more trenches with metal to form one or more barrier metal walls.

12. The method of claim 11, further comprising forming a first layer of metal interconnect on the interlayer dielectric after filling the or more trenches with metal.

13. The method of claim 12 wherein, after filling the one or more trenches with metal, the method further comprises depositing a capping layer directly on the interlayer dielectric to embed the one or more barrier metal walls in the interlayer dielectric and separating the one or more barrier metal walls from the first layer of metal interconnect.

14. The method of claim 13, further comprising:
masking and etching to open a contact hole through the interlayer dielectric and adjacent to the one or more barrier metal walls, and through the etch-stop layer to a surface of the at least one gate electrode; and
depositing metal material filling the contact hole to form a contact to electrically connect the at least one gate electrode to a first metal interconnect of the first layer of metal interconnect;
wherein the one or more barrier metal walls and the contact are separated by interlayer dielectric and electrically isolated from each other.

15. The method of claim 13 where the interlayer dielectric is a dielectric oxide formed from tetraethoxysilane by chemical vapor deposition, and the etch-stop layer is a layer of silicon oxynitride deposited by chemical vapor deposition.

16. The method of claim 11 where the metal with which the trenches are filled is tungsten.

17. The method of claim 11 further comprising:
forming an isolation structure from a backside surface of the semiconductor substrate opposite to the front side surface between the first photodiode and the second photodiode, wherein the isolations structure is aligned with the one or more barrier metal walls;
forming a metal grid that defines a first aperture aligned with the first photodiode and a second aperture aligned with the second photodiode on the backside surface of the semiconductor substrate, wherein the metal grid is aligned with the one or more barrier metal walls;
depositing a neutral-density filter in the first aperture aligning with the first photodiode; and
depositing color filter material into the first aperture on the neutral-density filter and into the second aperture aligned with the second photodiode.

18. The method of claim 11, wherein the first photodiode has a first full well capacity smaller than a second full well capacity of the second photodiode.

19. The method of claim 18, wherein the process of forming the plurality of photodiodes further includes forming a third photodiode, a fourth photodiode and a fifth photodiode, wherein the second, the third photodiode, the fourth photodiode and the fifth photodiode surround the first photodiode; wherein each of the third photodiode, the fourth photodiode and the fifth photodiode has the second full well capacity.

20. The method of claim 19, wherein forming one or more trenches through the interlayer dielectric comprises forming a first trench between the first photodiode and the second photodiode, a second trench between the first photodiode and third photodiode, a third trench between the first photodiode and fourth photodiode, and a fourth trench between the first photodiode and fifth photodiode; and wherein filling the one or more trenches with metal comprises filling the first, second, third, and fourth trenches to form a first barrier metal wall between the first photodiode and the second photodiode, a second barrier metal wall between the first photodiode and third photodiode, a third barrier wall between the first photodiode and fourth photodiode, and a fourth barrier metal wall between the first photodiode and fifth photodiode.
